(19) United States
(12) Patent Application Publication
(10) Pub. No.: US 2007/0279119 A1
(43) Pub. Date: Dec. 6, 2007

(54) GATE DRIVING DEVICE FOR DRIVING INSULATED GATE BIPOLAR TRANSISTOR AND METHOD OF DRIVING THE SAME

(75) Inventor: Yuichi Onozawa, Matsumoto City (JP)

Correspondence Address: ROSSI, KIMMS & McDOWELL LLP., P.O. BOX 826, ASHBURN, VA, 20146-0826, US

(73) Assignee: C/O FUJI ELECTRIC DEVICE TECHNOLOGY CO., LTD., Tokyo (JP)

(21) Appl. No.: 11/737,897

(22) Filed: Apr. 20, 2007

(30) Foreign Application Priority Data
Apr. 20, 2006 (JP) 2006-116584

(51) Int. Cl. H03K 17/60; H03K 17/06

(52) U.S. Cl. 327/377; 327/434

(57) ABSTRACT

A gate driving device includes an IGBT and a gate drive circuit, which includes a gate resistor and a gate drive unit. The gate of the IGBT is connected to the gate resistor, and the emitter of the IGBT is connected to a low voltage potential. The peak impurity concentration of the collector of the IGBT is equal to or greater than 1×10¹⁶ cm⁻³, and the time constant, which is the product of a gate input capacitance (Cg) of the IGBT and a resistance value of the gate resistor (Rg) is equal to or less than 500 ns. The IGBT is turned ON or OFF by inputting an ON or OFF signal respectively to the gate via the gate resistor. The gate driving device can lower the spike voltage and reduce the turn-off power loss at the same time in an inductive load circuit when the IGBT is turned off.

### BACKGROUND

A low-power consuming power conversion equipment is being developed. It is highly anticipated that reducing power loss in a power device (e.g., a switching device) plays a major role in developing such equipment. A spike voltage (a surge voltage), however, applied to the power device at the turn-off becomes high with the increase in the switching speed and the increase in the bus voltage (a power source voltage), resulting in severe operating duty applied to the power device. Because this spike voltage depends greatly upon the electric wiring inductance, it is important to reduce the electric wiring inductance to suppress the spike voltage. Nonetheless, there is a limitation to reducing the electric wiring inductance. Accordingly, it is desirable to reduce the gradient of current at the turn-off (current reduction rate, i.e., −dl/dt), which is determined by the device.

First, structures of conventional IGBTs will be explained referring to FIGS. 7A-7D, which schematically illustrate cross sectional views of the IGBTs. FIG. 7A shows a Punch Through type (hereinafter referred to as PT type) IGBT with a planar type gate structure. FIG. 7B shows a Non-Punch Through type (hereinafter referred to as NPT type) IGBT with the planar type gate structure. FIG. 7C shows a Field Stop type (hereinafter referred to as FS type) IGBT with the planar type gate structure. FIG. 7D shows the NPT type IGBT with a trench type gate structure instead of the planar type gate structure shown in FIG. 7B. A collector metal electrode on its rear surface is not shown in FIGS. 7A-7D.

The features of these well-known structures now will be now explained. The structure of the PT type IGBT of FIG. 7A comprises a substrate of an epitaxial silicon wafer consisting of a p⁺ collector layer 31 and an n⁺ buffer layer 32 and an n⁻ drift layer 33. A p well layer 34 and an n⁺ emitter layer 35 are formed in the substrate by diffusion. A gate electrode 37 is formed via a gate oxide film 36 on the substrate. An interlayer insulation film 38 is formed on the gate electrode. An emitter electrode 39 is formed to contact the p well layer 34 and the n⁺ emitter layer 35. The thickness of the substrate of the PT type IGBT is approximately 350 μm due to use an epitaxial silicon wafer.

The structure of the NPT type IGBT of FIG. 7B uses a Floating Zone (hereinafter referred to as FZ) wafer to form the substrate, in which the p well layer 34 and the n⁺ emitter layer 35 are formed in its surface. A p⁺ layer 41 is formed by ion implantation after polishing the rear surface of the substrate. The FZ wafer not only has the cost advantage, but also has low crystal defects, making it highly reliable. The thickness of the substrate of the NPT type IGBT is approximately 100 μm.

The structure of the FS type IGBT of FIG. 7C also uses the FZ substrate, with the p well layer 34 and the n⁺ emitter layer 35 formed in its surface. An n type field stop layer 43 and the p⁺ collector layer 41 are formed by ion implantation after polishing the rear surface of the substrate. In the NPT type IGBT, it is necessary to make the n⁻ drift layer 42 thick so that a depletion layer does not reach the collector layer 41 at the off state. But in the FS type IGBT, it is possible for the thickness of the n⁻ drift layer 42 to be thin in comparison with the NPT type IGBT due to the field stop layer 43 for stopping the depletion layer. This can reduce the on-state voltage. In addition, because the thickness of the n⁻ drift 42 is thin in the FS type IGBT, there is a little excess carrier, and there is a little remaining width of a neutrality region under the state where the depletion layer has finished spreading. This can reduce the turn-off power loss.

FIG. 7D illustrates the NPT type IGBT with the trench type gate structure. A trench 45 is formed in the surface of the substrate and a gate electrode 46 of a polysilicon is formed in the trench 45 via a gate oxide 47. Because the cell density in the trench gate type structure can largely increase in comparison with in the planar type structure, the on-voltage drop in a channel section 49 can be suppressed. In addition, because a portion of a JFET 50 sandwiched by channel sections 48 peculiar to the planar gate type structure (see FIG. 7B) does not exist in the trench gate type structure, the on-voltage drop of this portion can be completely eliminated. As a result, the on-state voltage can be largely reduced. In addition, the PT type IGBT and the FS type IGBT with the trench type gate structure can be formed respectively corresponding to the PT type IGBT of FIG. 7A and the FS type IGBT of FIG. 7C. The NPT type IGBT of FIG. 7D corresponds to the NPT type IGBT of FIG. 7B having the planar type gate structure.

The switching operation now follows referring to FIG. 5, which is a circuit diagram showing an example of an inductive load circuit. One end of an inductive load 24 and an anode of a diode 25 are connected to the collector of the IGBT 21. Another end of the inductive load 24 and a cathode of the diode 25 are connected to a high potential side of a high voltage power source 26. A ground (a low potential side) of the high voltage power source 26 is connected to the emitter of the IGBT 21. The gate of the IGBT 21 is connected to a gate resistor Rgo of a gate drive circuit 22, and the emitter of the IGBT 21 is connected to the low potential side of the gate drive circuit 22. The gate drive circuit 22 includes a gate drive unit 23 and the gate resistor Rgo. A low voltage power source is included in the gate drive unit 23. A portion indicated by a reference symbol K relates to the present invention, which includes the IGBT 21 and the gate drive circuit 22.

The circuit operation of FIG. 5 follows. An on signal is input into the gate of the IGBT 21 via the gate resistor Rgo to turn on the IGBT 21. Collector current IC flows from a high voltage power source through the inductive load 24 and the IGBT 21 after the IGBT 21 is turned on. An off-signal is input into the gate of the IGBT 21 through the gate resistor Rgo to turn off the IGBT 21. When the IGBT 21 is in the off state, charges accumulated in a gate input capacitance Cg of the IGBT 21 discharge through the gate resistor Rgo to the gate drive unit 23 so that the gate voltage becomes low. While the gate voltage is larger than the gate threshold voltage, electrons are injected from the emitter layer of the IGBT 21 into the drift layer through the channel. In addition, because the voltage is being applied between the collector electrode and the emitter electrode of the IGBT 21, the depletion layer spreads toward the collector layer to sweep out electrons to the collector layer side. The electrons injected through the channel and the electrons swept out are recombined with holes injected from the collector layer into the drift layer. Carriers in the drift layer decrease by this recombination. Then, the collector current IC of the IGBT 21 decreases, and a voltage VCE between the collector and the emitter rises according to the product (−Ldl/dt) of a current reduction ratio (−dl/dt) and an electric wiring inductance L, generating a spike voltage VSP is generated. FIG. 6 is an operation waveform chart of the collector current IC and the collector voltage VCE in the circuit of FIG. 5.

In addition, Japanese Patent Laid-Open No. 2003-125574 discloses that “to provide a gate drive circuit which realizes low-loss turn-on, a plurality of resistors Rg (ext) and Rg (int) are arranged, in series between an IGBT and a transistor at the final stage of the gate drive circuit, and between them capacitance C (ext) is arranged so as to make them juxtaposed in connection between the gate and the emitter of the IGBT.”

Moreover, Japanese Patent Laid-Open No. 10-75164 discloses that “to provide a gate drive circuit which can be turned off with a small loss and a low surge voltage (spike voltage), the gate signal supplying circuit of an IGBT constituting a main circuit of a power converter is provided as a duplex constitution of two circuits. The gate signal supplying circuit is composed of a switching circuit for control for a gate voltage for turn-on and for a gate voltage for turn-off, and a gate resistance. After a turn-off operation of one switching circuit for control, a turn-off operation of the other switching circuit for control is executed after the lapse of a fixed time.”

Moreover, Japanese Patent Laid-Open No. 2000-40951 discloses that “to improve stability of current density, to inhibit the concentration of current and oscillation and to improve reliability, the injection of electrons is stopped before the boosting of voltage between main electrodes by dropping the voltage of a control electrode to be not more than a threshold voltage Vth of a semiconductor device before main current moves to fall time when the semiconductor device is turned off.”

Moreover, Japanese Patent Laid-Open No. 2004-311481 discloses that “to obtain a semiconductor device that can be reduced in on-resistance without increasing turn-off loss, in a PT type IGBT having a planar type structure, an n type buffer layer having a width of 40 μm and a peak impurity concentration of 1×10¹⁶ cm⁻³ is formed on the rear surface of an n base layer having an impurity concentration of 1×10¹³ cm⁻³ and a p type emitter layer composed of a p⁻ type layer having a thickness of 5 μm and the peak impurity concentration of 1×10¹⁶ cm⁻³ and a p⁺ layer having a thickness of 1 μm and the peak impurity concentration of 7×10¹⁷ cm⁻³ is formed on the rear surface of the n type buffer layer.”

In a MOSFET or an IGBT the spike voltage VSP at the turn-off generally can be lowered by increasing the resistance value of the gate resistor Rgo (disposed outside of a semiconductor chip) of a gate drive circuit shown in FIG. 5 to lower −dl/dt. When the resistance value of the gate resistor Rgo is set large, however, electric charges that get accumulated in a gate input capacitance Cg are not easily discharged. Moreover, the mirror period (a period when a depletion layer is extended, i.e., a period when a carrier is swept out) becomes long. As a result, there is a problem in that the turn-off power loss increases.

Thus, in the conventional gate drive circuit 22, when the resistance value of the gate resistor Rgo is set large to lower the spike voltage VSP, the turn-off power loss increases. Accordingly, there remains a need for an IGBT and a gate drive circuit that can lower the spike voltage while reducing the turn-off power losses. The present invention addresses this need.

### SUMMARY OF THE INVENTION

The present invention relates to a gate driving device for driving an Insulated Gate Bipolar Transistor (IGBT) and a method of driving the same.

One aspect of the present invention is a gate driving device, which can include an IGBT having a collector, an emitter, and a gate, and a gate drive circuit having a gate resistor. The gate resistor is directly connected to the gate of the IGBT. The peak impurity concentration of the collector of the IGBT is equal to or greater than 1×10¹⁶ cm⁻³, and the time constant, which is the product of a gate input capacitance of the IGBT and a resistance value of the gate resistor, is equal to or less than 500ns.

The resistance value of the gate resistor is in a range where the spike voltage applied between the collector and the emitter of the IGBT becomes higher as the resistance value of the gate resistor becomes larger.

The IGBT can have a planar gate type structure or a trench gate type structure. The IGBT can be one of a Non Punch Through type IGBT, a Punch Through type IGBT, or a Field Stop type IGBT.

The gate drive circuit further includes a gate drive unit connected to the gate resistor and the emitter of the IGBT.

Another aspect of the present invention is a method of driving the IGBT described above. The method includes connecting the gate resistor directly to the gate of the IGBT, and turning the IGBT ON or OFF by inputting an ON or OFF signal respectively to the gate via the gate resistor. The peak impurity concentration of the collector of the IGBT is equal to or greater than 1×10¹⁶ cm⁻³, and the time constant, which is the product of a gate input capacitance of the IGBT and the resistance value of the gate resistor, is equal to or less than 500ns.

### BRIEF DESCRIPTION OF THE DRAWINGS

FIG. 1 is a graph showing a spike voltage VSP when a resistance value of a gate resistor Rg of a gate drive circuit is changed as a parameter in a peak impurity concentration of a collector layer in an NPT type IGBT.

FIG. 2 is a diagram showing a gate driving device for driving an IGBT according to the present invention.

FIG. 3 is a graph showing the trade-off relation between the spike voltage and the turn-off power loss, taking the resistance value of a gate resistor Rg and the peak impurity concentration of a collector layer as parameters.

FIG. 4 is a graph showing the relation between the spike voltage and the time constant, which is the product of a gate input capacitance Cg of an IGBT at VCE (a voltage between a collector and an emitter)=0V and the resistance value of the gate resistor Rg.

FIG. 5 is a circuit diagram showing an example of an inductive load circuit.

FIG. 6 is an operation waveform chart of a collector current IC and a collector voltage VCE in the circuit of FIG. 5.

FIGS. 7A to 7D are cross-sectional views showing conventional IGBT structures.

### DETAILED DESCRIPTION

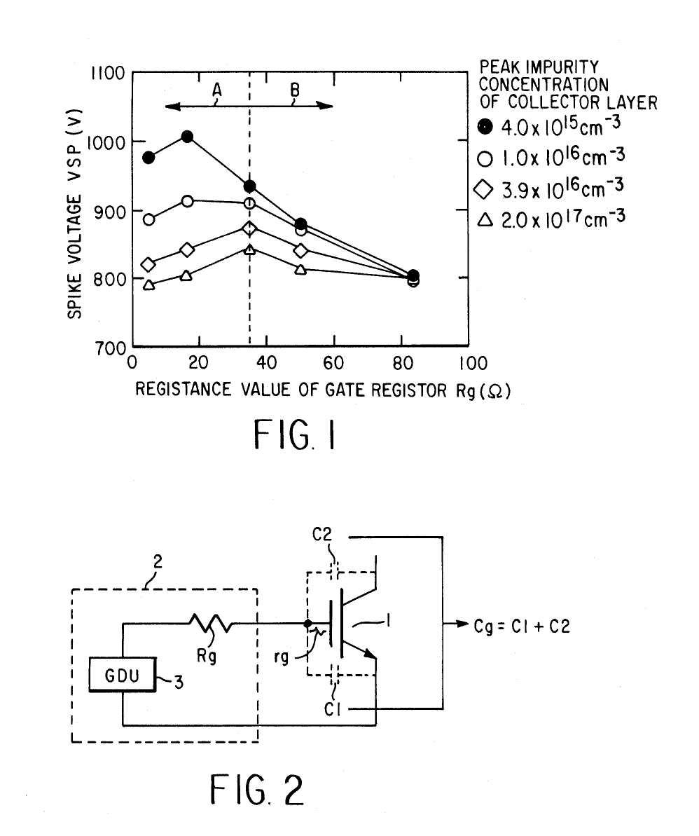

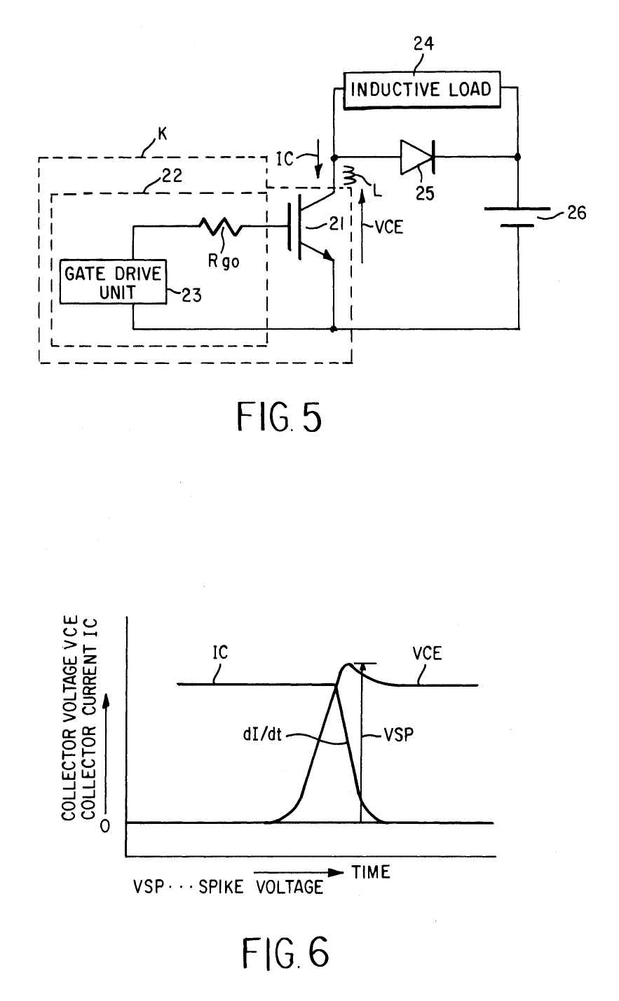

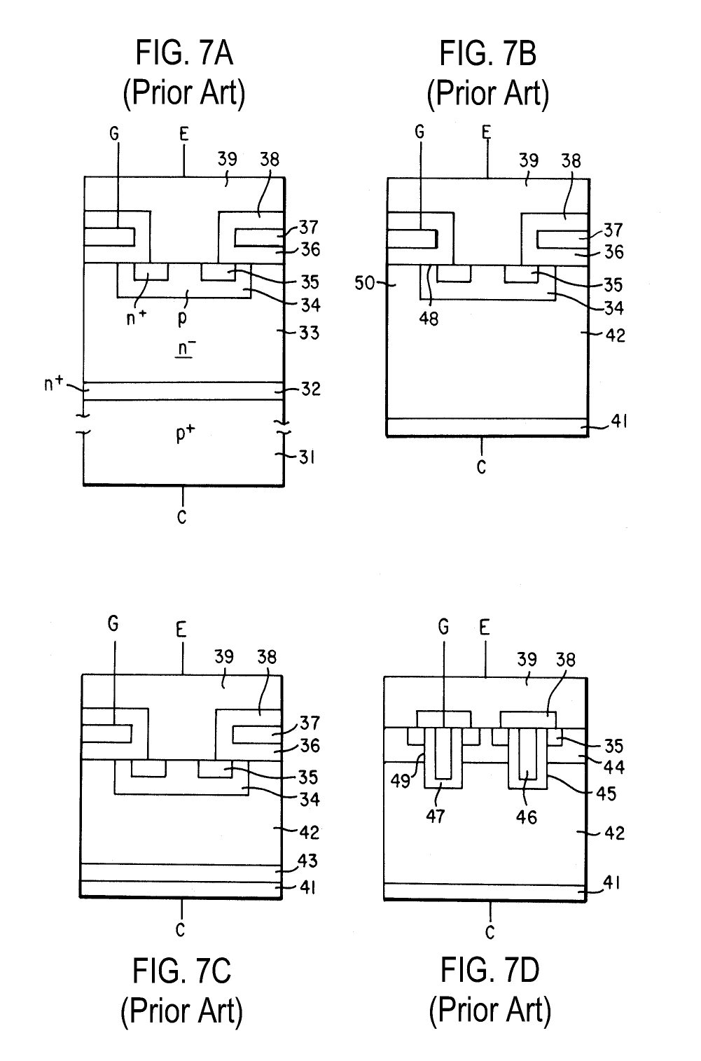

When an IGBT is turned off in an inductive load circuit such as FIG. 5, there is a range of resistance values of a gate resistor Rg (a resistor corresponding to Rgo of FIG. 5) where both −dl/dt and the spike voltage VSP become higher as the resistance value of the gate resistor Rg becomes larger (in the range of a small resistance value of the gate resistor Rg). This characteristic of the IGBT is different from that of a MOSFET. It will be explained more in detail. FIG. 1 is a graph showing the spike voltage VSP when the resistance value of a gate resistor Rg of a gate drive circuit is changed as a parameter in a peak impurity concentration of a collector layer in an NPT type IGBT. As shown in FIG. 1, the spike voltage VSP becomes higher as the resistance value of the gate resistor Rg becomes larger, and the spike voltage VSP becomes lower as the resistance value of the gate resistor Rg becomes even larger. The reason for this can be explained as follows. The peak impurity concentration of the collector layer of the IGBT in FIG. 1 is respectively 4.0×10¹⁵ cm⁻³, 1.0×10¹⁶ cm⁻³, 3.9×10¹⁶ cm⁻³ and 2.0×10¹⁷ cm⁻³.

In FIG. 1, because the turn-off current of the IGBT is dominated by a quantity of carriers that are recombined with minority carriers and swept out by spreading of a depletion layer in the range A where the resistance value of the gate resistor Rg is comparatively small, −dl/dt at the turn-off does not become low even when the resistance value of the gate resistor Rg is increased. This quantity of carriers depends upon injection efficiency of carriers from the collector layer into the drift layer. The injection efficiency increases and then the quantity of holes injected into the drift layer increases when the impurity concentration of the collector layer increases.

In contrast, in the range A, the quantity of carriers stored in the drift layer decreases by recombination of minority carriers due to the timing of the turn-off becoming late (a storage period becoming long) when the resistance value of the gate resistor Rg is increased. As a result, −dl/dt at the turn-off becomes high and the spike voltage VSP increases. In the range B of a comparatively large resistance value of the gate resistor Rg, current flowing through a MOSFET in the surface (current flowing through a channel) becomes dominant, so that the gate voltage falls more slowly as the resistance value of the gate resistor Rg becomes larger. As a result, −dl/dt at the turn-off becomes low, and the spike voltage VSP in turn decreases. The resistance value of Rg in the range B corresponds to the resistance value of a conventional gate resistor Rgo.

In other words, when the spike voltage VSP is measured by changing the resistance value of the gate resistor Rg from the comparatively large resistance value of the range B toward the comparatively small resistance value of the range A, the spike voltage VSP becomes a local maximum in the range A and then turns in the opposite direction to decrease from the local maximum. The turn-off power loss also can be reduced by using the resistance value of the gate resistor Rg that can lower the spike voltage VSP in the range A. Further, because injection of holes from the collector layer becomes dominant in the range A, −dl/dt at the turn-off can be lowered when this injection is increased, lowering the spike voltage.

Thus, −dl/dt at the turn-off can be lowered to a value determined by recombination of minority carriers stored in the drift layer regardless of the resistance value of the gate resistor Rg when the injection of holes from the collector layer is increased by increasing the peak impurity concentration of the collector layer. Therefore, shortening the mirror period by setting the resistance value of the gate resistor Rg small can lower the turn-off power loss.

The present invention can be applied to improve the trade-off between the spike voltage VSP and the turn-off power loss by setting the impurity concentration of the collector layer of the IGBT related to injection efficiency of holes and the resistance value of the gate resistor Rg in a respectively predetermined range. The gate driving device, i.e., an IGBT and a gate drive circuit for driving the IGBT, according to the present invention will now be explained in detail with reference to the attached drawings.

FIG. 2, which corresponds to the portion indicated by reference symbol K of FIG. 5, is a diagram showing the gate driving device according to the present invention. The gate driving device includes an IGBT 1 and a gate drive circuit 2 for driving the IGBT. The gate drive circuit 2 comprises a gate resistor Rg and a gate drive unit 3. The gate of the IGBT 1 is directly connected to the gate resistor Rg, and the emitter of the IGBT 1 is connected to the low voltage side. The gate drive unit 3 includes a low voltage power supply for driving the gate of the IGBT 1. The low voltage power supply is not specifically shown in FIG. 2.

When the time constant, which is the product of a gate input capacitance Cg of the IGBT and the resistance value of the gate resistor, is equal to or less than 500 ns, and the peak impurity concentration of the collector layer of the IGBT is equal to or greater than 1×10¹⁶ cm⁻³, the spike voltage can be lowered while reducing the turn-off power loss. The gate input capacitance Cg is the sum of the capacitance C1 between the gate and the emitter, and the capacitance C2 between the gate and the collector.

In addition, as shown in FIG. 4, when the peak of the spike voltage is equal to or less than 500 ns (the neighborhood of 250 ns) and when the impurity concentration of the collector layer is at 1×10¹⁶ cm⁻³, the time constant at the peak spike voltage can be set as a maximum value (250 ns) and the time constant of smaller than 250 ns is more preferable to improve the spike voltage and the turn-off power loss in comparison with the time constant of 500 ns. The present technique can be applied to the respective IGBT where the gate structure is planar gate type or trench gate type and an element structure is NPT type, PT type, or FS type in view of the element.

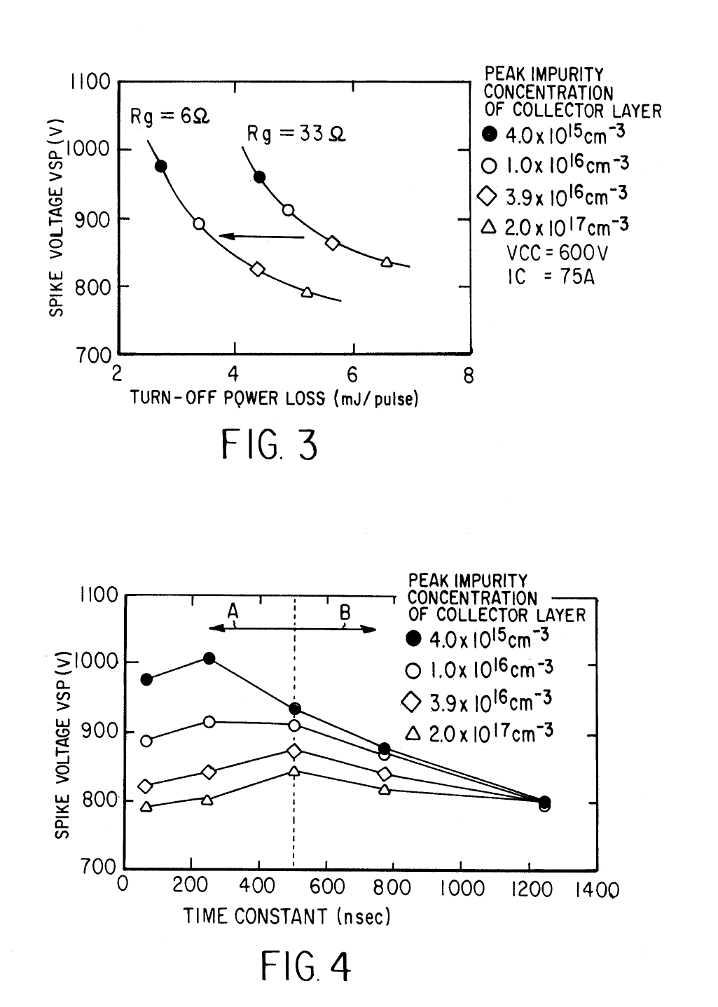

FIG. 3 is a graph showing the trade-off relation between the spike voltage and the turn-off power loss in terms of a resistance value as a parameter of a gate resistor Rg and a peak impurity concentration of a collector layer as another parameter. It is understood that the trade-off improves by changing the resistance value of the gate resistor Rg from 33 Ω (corresponding to the time constant of 500 ns) to 6 Ω (corresponding to that of 90 ns). The peak impurity concentration of the collector layer is respectively 4.0×10¹⁵ cm⁻³, 1.0×10¹⁶ cm⁻³, 3.9×10¹⁶ cm⁻³ and 2.0×10¹⁷ cm⁻³.

FIG. 4 is a graph showing the relation between the spike voltage and the time constant (which is the product of the gate input capacitance Cg of an IGBT at VCE (a voltage between a collector and an emitter)=0V and the resistance value of the gate resistor Rg). The parameter is the peak impurity concentration of the collector layer, and the peak impurity concentration is respectively 4.0×10¹⁵ cm⁻³, 1.0×10¹⁶ cm⁻³, 3.9×10¹⁶cm ^{31 3}, and 2.0×10¹⁷ cm^{-3.}

In view of FIG. 4, the spike voltage can be lowered when the impurity concentration of the collector layer is equal to or greater than 1.0×10¹⁶ cm⁻³ and the product of the gate input capacitance Cg and the resistance value of the gate resistor Rg is equal to or lower than 500 ns. In addition, the IGBT with a normal-rated voltage equal to or greater than several hundred volts and a normal-rated current equal to or greater than several tens of amperes has a gate resistor rg of equal to or less than 1 Ω in a semiconductor chip which is negligibly smaller than the gate resistor Rg of the gate drive circuit. Therefore, the spike voltage shown in FIG. 4 hardly depends upon the gate resistor rg.

According to the present invention, the IGBT is formed with the peak impurity concentration of the collector layer of the IGBT being equal to or greater than 1×10¹⁶ cm⁻³ and is driven by the gate drive circuit having the time constant, which is the product of the gate input capacitance of the IGBT and the resistance value of the gate resistor, being equal to or less than 500 ns. This lowers the spike voltage while at the same time reduces the turn-off power loss. In other words, the trade-off between the spike voltage VSP and turn-off power loss of the IGBT at turn-off can be improved.

While the present invention has been particularly shown and described with reference to preferred embodiment thereof, it will be understood by those skilled in the art that the foregoing and other changes in form and details can be made therein without departing from the spirit and scope of the present invention. All modifications and equivalents attainable by one versed in the art from the present disclosure within the scope and spirit of the present invention are to be included as further embodiments of the present invention. The scope of the present invention accordingly is to be defined as set forth in the appended claims.

This application is based on, and claims priority to, JP PA 2006-116584 filed on 20 Apr. 2006. The disclosure of the priority application, in its entirety, including the drawings, claims, and the specification thereof, is incorporated herein by reference.

What is claimed is:

1. A gate driving device for driving an Insulated Gate Bipolar Transistor (IGBT) comprising:
an IGBT having a collector, an emitter, and a gate; and
a gate drive circuit having a gate resistor,
wherein the gate resistor is directly connected to the gate of the IGBT,
wherein a peak impurity concentration of the collector of the IGBT is equal to or greater than 1×10¹⁶ cm⁻³, and
wherein a time constant, which is the product of a gate input capacitance of the IGBT and a resistance value of the gate resistor, is equal to or less than 500 ns.

2. The gate driving device according to claim 1, wherein the resistance value of the gate resistor is in a range where a spike voltage applied between the collector and the emitter of the IGBT becomes higher as the resistance value of the gate resistor becomes larger.

3. The gate driving device according to claim 1, wherein the IGBT has a planar gate type structure or a trench gate type structure.

4. The gate driving device according to claim 2, wherein the IGBT has a planar gate type structure or a trench gate type structure.

5. The gate driving device according to claim 3, wherein the IGBT is one of a Non Punch Through type IGBT, a Punch Through type IGBT, or a Field Stop type IGBT.

6. The gate driving device according to claim 4, wherein the IGBT is one of a Non Punch Through type IGBT, a Punch Through type IGBT, or a Field Stop type IGBT.

7. The gate driving device according to claim 1, wherein the gate drive circuit further includes a gate drive unit connected to the gate resistor and the emitter of the IGBT.

8. A method of driving an Insulated Gate Bipolar Transistor (IGBT) with a gate drive circuit having a gate resistor, the IGBT having a collector, an emitter, and a gate, the method comprising the steps of:
connecting the gate resistor directly to the gate of the IGBT; and
turning the IGBT ON or OFF by inputting an ON or OFF signal respectively to the gate via the gate resistor,
wherein a peak impurity concentration of the collector of the IGBT is equal to or greater than 1×10¹⁶ cm⁻³, and
wherein a time constant, which is the product of a gate input capacitance of the IGBT and a resistance value of the gate resistor, is equal to or less than 500 ns.

9. The method according to claim 8, wherein the resistance value of the gate resistor is in a range where a spike voltage applied between the collector and the emitter of the IGBT becomes higher as the resistance value of the gate resistor becomes larger.

10. The method according to claim 8, wherein the IGBT has a planar gate type structure or a trench gate type structure.

11. The method according to claim 9, wherein the IGBT has a planar gate type structure or a trench gate type structure.

12. The method according to claim 10, wherein the IGBT is one of a Non Punch Through type IGBT, a Punch Through type IGBT, or a Field Stop type IGBT.

13. The method according to claim 11, wherein the IGBT is one of a Non Punch Through type IGBT, a Punch Through type IGBT, or a Field Stop type IGBT.
